(19) United States
(12) Patent Application Publication
(10) Pub. No.: US 2007/0262347 A1
(43) Pub. Date: Nov. 15, 2007

(54) DISPLAY SUBSTRATE, METHOD FOR MANUFACTURING THE SAME AND DISPLAY APPARATUS HAVING THE SAME

(76) Inventor: Chun-Gi You, Gyeonggi-do (KR)

Correspondence Address: MACPHERSON KWOK CHEN & HEID LLP, 2033 GATEWAY PLACE, SUITE 400, SAN JOSE, CA, 95110, US

(21) Appl. No.: 11/697,983

(22) Filed: Apr. 9, 2007

(30) Foreign Application Priority Data
May 10, 2006 (KR) 2006-41807

(51) Int. Cl. H01L 27/10

(52) U.S. Cl. 257/202

(57) ABSTRACT

A display substrate having a high aperture ratio includes gate and source metallic patterns, first and second gate insulating layers, and a pixel electrode. The gate metallic pattern includes a gate line, a gate electrode and a first storage electrode. The first gate insulating layer covers at least one of the gate electrode and the first storage electrode. The second gate insulating layer is patterned to expose the first gate insulating layer on the first storage electrode. The source metallic pattern includes a second storage electrode contacting a source line and the first gate insulating layer on the first storage electrode. The pixel electrode is electrically connected to a switching element. Therefore, the display substrate having the high aperture ratio may be obtained to enhance luminance of a display image.

### CROSS-REFERENCE TO RELATED APPLICATIONS

This application claims priority under 35 USC § 119 to Korean Patent Application No. 2006-41807 filed on May 10, 2006 in the Korean Intellectual Property Office (KIPO), the contents of which are herein incorporated by reference in their entirety.

### BACKGROUND OF THE INVENTION

1. Field of the Invention

The present invention relates to a display substrate and, more particularly, to a display substrate having a high aperture ratio and a method for manufacturing the display substrate.

2. Description of the Related Art

Generally, a liquid crystal display (LCD) apparatus includes a display substrate and a counter substrate. The counter substrate is assembled with the display substrate and a liquid crystal layer between the display substrate and the counter substrate. Gate lines and source lines intersecting the gate lines as well as switching elements electrically connected to the gate and source lines, and pixel electrodes electrically connected to the switching elements, are formed on the display substrate. Each of the switching elements includes a gate electrode, a channel, a source electrode and a drain electrode. The gate electrode is extended from each of the gate lines. The channel is insulated from and overlaps the gate electrode. The source electrode is formed from each of the source lines and is electrically connected to the channel. The drain electrode is separated from the source electrode, and is electrically connected to the channel. LCDs having high luminance are desired. However, increasing the luminance of the backlight has the disadvantage of increasing power consumption.

### SUMMARY OF THE INVENTION

According to one aspect of the present invention, a display substrate having a high aperture ratio that enhances the luminance of a display image includes a gate metallic pattern, a first gate insulating layer, a second gate insulating layer, a source metallic pattern and a pixel electrode. The gate metallic pattern includes a gate line, a gate electrode of a switching element and a first storage electrode. The first gate insulating layer covers at least one of the gate electrode and the first storage electrode. The second gate insulating layer is patterned to expose the first gate insulating layer on the first storage electrode. The source metallic pattern includes a second storage electrode contacting a source line and the first gate insulating layer on the first storage electrode. The pixel electrode is electrically connected to the switching element.

An example method for manufacturing the display substrate according to the present invention includes forming a gate metallic pattern on a base substrate from a gate metallic layer, the gate metallic pattern including a gate line, a gate electrode of a switching element and a first storage electrode; forming a first gate insulating layer on the base substrate having the gate metallic pattern; patterning the first gate insulating layer to cover at least one gate electrode and the first storage electrode; forming a second gate insulating layer, the second gate insulating layer being formed on the base substrate having the patterned first gate insulating layer and being patterned to expose the first gate insulating layer on the first storage electrode; forming a second storage electrode, the second storage electrode being formed from a source metallic layer to contact a source line and the first gate insulating layer on the first storage electrode, the first gate insulating layer being exposed through the second gate insulating layer; and forming a pixel electrode, the pixel electrode being formed from a transparent conductive layer to be electrically connected to the switching element.

An example display apparatus according to the present invention includes a display substrate and a counter substrate. The display substrate includes a first gate insulating layer patterned to cover at least one gate electrode of a switching element and a first storage electrode, a second gate insulating layer being patterned to expose the first gate insulating layer on the first storage electrode, a second storage electrode contacting the first gate insulating layer on the first storage electrode, and a pixel electrode electrically connected to the switching element. The counter substrate is assembled with the display substrate to receive a liquid crystal layer between the display substrate and the counter substrate, and a common electrode that faces the pixel electrode formed on the counter substrate.

### According to an aspect of the present invention, the display substrate having the high aperture ratio may be obtained,

### BRIEF DESCRIPTION OF THE DRAWINGS

The above and other features and advantages of the present invention will become more apparent by describing in detailed example embodiments thereof with reference to the accompanying drawings, in which:

FIG. 1 is a plan view illustrating a display apparatus according to an example embodiment of the present invention;

FIG. 2 is a cross-sectional view taken along a line I-I′ in FIG. 1; and

FIGS. 3 to 9 are process views illustrating a method for manufacturing the display substrate in FIG. 2.

### DESCRIPTION OF THE EMBODIMENTS

In the drawings, the size and relative sizes of layers and regions may be exaggerated for clarity. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the apparatus in use or operation in addition to the orientation depicted in the figures. For example, if the apparatus in the figures is turned over, elements described as “below” or “beneath” other elements or features would then be oriented “above” the other elements or features. Thus, the term “below” can encompass both an orientation of above and below. The apparatus may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of an apparatus and are not intended to limit the scope of the invention.

Hereinafter, the present invention will be explained in detail with reference to the accompanying drawings.

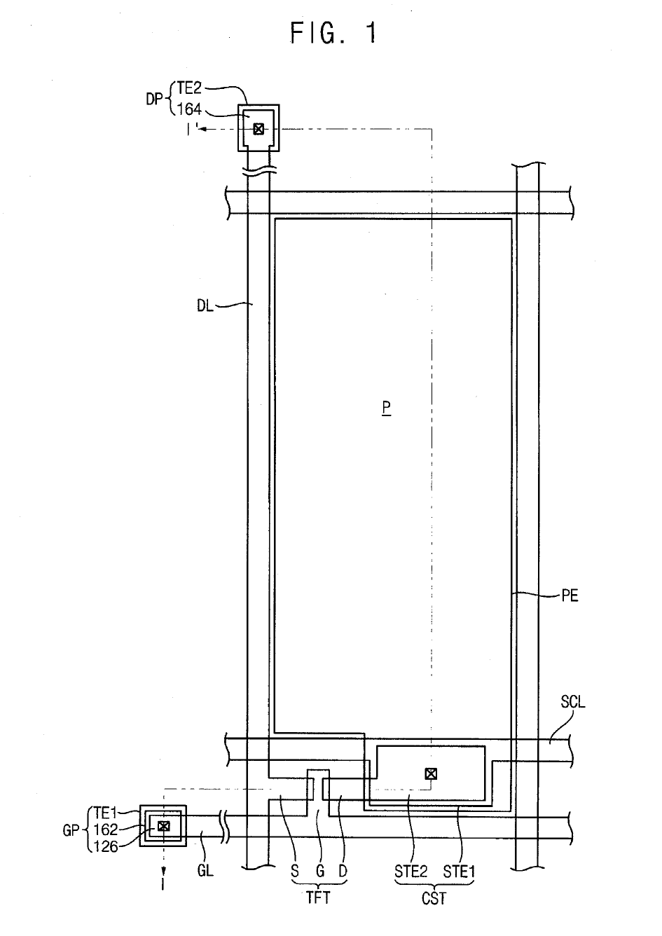

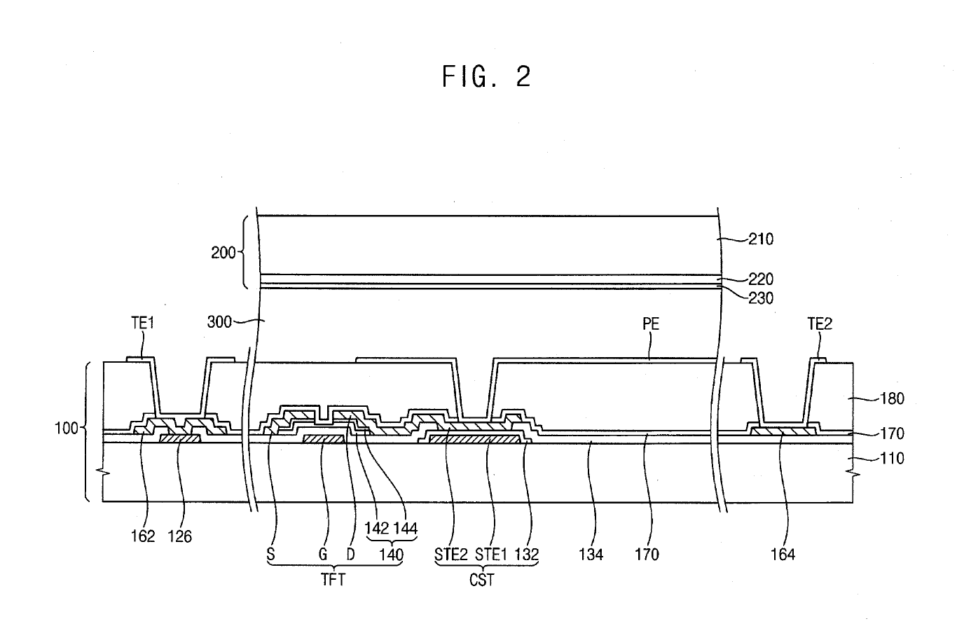

FIG. 1 is a plan view illustrating a display apparatus according to an example embodiment of the present invention, and FIG. 2 is a cross-sectional view taken along a line I-I′ in FIG. 1.

Referring to FIGS. 1 and 2, the display apparatus includes a display substrate 100 and a counter substrate 200. The counter substrate 200 is combined with the display substrate 100 to receive a liquid crystal layer 300 between the display substrate 100 and the counter substrate 200. The display substrate 100 includes a first base substrate 110, a plurality of pixel portions P and a pixel electrode PE. The plurality of pixel portions P is formed on the first base substrate 110 in a matrix shape, and the pixel electrode PE is formed on each of pixel portions P. The counter substrate 200 includes a second base substrate 210, a color filter layer 220 and a common electrode 230. The color filter layer 220 is formed on the second base substrate 210, and the common electrode 230 is formed on the color filter layer 220 to correspond to the pixel electrode PE.

For example, the display substrate 100 includes a plurality of gate lines GL, a plurality of source lines DL, a plurality of switching elements TFT, a plurality of pixel electrodes PE and a storage capacitor CST formed thereon. The storage capacitor CST is electrically connected to a storage line SCL. A common voltage is applied to the storage line SCL.

Each of the gate lines GL is formed from a gate metallic layer, and extends along a first direction. An example of a material that may be used for the gate metallic layer may be a metal including copper (Cu), aluminum (Al), silver (Ag), molybdenum (Mo), or an alloy thereof, or a metal including chromium (Cr), tantalum (Ta) or titanium (Ti). The gate metallic layer may be formed with a single-layer structure or with a multi-layer structure including different metals. Preferably, the gate metallic layer is formed with a Mo/Al multi-layer structure including aluminum (Al) and molybdenum (Mo) that have low resistance.

A gate signal is applied to a gate pad portion GP formed on an end portion 126 of each of the gate lines GL. The gate pad portion GP includes a connecting pattern 162 and a first pad pattern TE1. The end portion 126 of each of the gate lines GL is formed from the gate metallic layer, the connecting pattern 162 is formed from a source metallic layer, and the first pad pattern TE1 is formed from a transparent conductive layer.

Each of the source lines DL is formed from the source metallic layer, and extends along a second direction intersecting the first direction. An example of a material that may be used for the source metallic layer may be a metal including copper (Cu), aluminum (Al), silver (Ag), molybdenum (Mo), or an alloy thereof, or a metal including chromium (Cr), tantalum (Ta) or titanium (Ti). The source metallic layer may be formed with a single-layer structure or with a multi-layer structure including different metals. Preferably, the source metallic layer is formed using a metal including molybdenum (Mo) or a molybdenum alloy.

A source signal is applied to a source pad portion DP formed on an end portion 164 of each of the source lines DL. The source pad portion DP includes a second pad pattern TE2. The end portion 164 of each of the source lines DL is formed from the source metallic layer, and the second pad pattern TE2 is formed from the transparent conductive layer.

Each of the switching elements TFT is formed on the plurality of pixel portions P that are defined by the gate lines GL and the source lines DL. Each of the switching elements TFT includes a gate electrode G electrically connected to each of the gate lines GL, a source electrode S electrically connected to each of the source lines DL, and a drain electrode D separated from the source electrode S and electrically connected to the source electrode S through a channel portion 140. At least one of the first gate insulating layer 132 and the second gate insulating layer 134 is formed between the gate electrode G and the channel portion 140. Preferably, the first and second gate insulating layers 132 and 134 may be sequentially formed on the gate electrode G, or the first gate insulating layer 132 may be formed on the gate electrode G with the single-layer structure. The first gate insulating layer 132 includes silicon oxide having a thickness of about 500 Å to about 1,200 Å, and the second insulating layer 134 includes silicon nitride having a thickness of about 3,000 Å to about 4,500 Å. FIG. 2 illustrates that only the second gate insulating layer 134 is formed between the gate electrode G and the channel portion 140.

The pixel electrodes PE are electrically connected to the switching elements TFT. Each of the pixel electrodes PE is electrically connected to the drain electrode D of each of the switching elements TFT, and is formed on each of the pixel portions P. Each of the pixel electrodes PE is formed from the transparent conductive layer. An example of a material that may be used for the transparent conductive layer may include an oxide material or a nitride material that includes at least one of indium (In), tin (Sn), zinc (Zn), aluminum (Al) and gallium (Ga).

The storage capacitor CST includes a first storage electrode STE1, the first gate insulating layer 132 and a second storage electrode STE2. The first storage electrode STE1 is electrically connected to the storage line SCL to which the common voltage is applied. The second storage electrode STE2 faces the first storage electrode STE1.

The first storage electrode STE1 is formed from the gate electrode layer, and the second storage electrode STE2 is formed from the source electrode layer. The first gate insulating layer 132 includes a highly insulating material, and is thinner than the second gate insulating layer 134. Preferably, the first gate insulating layer 132 includes the silicon oxide having the thickness of about 500 Å to about 1,200 Å.

A capacitance Cstg of the storage capacitor CST is defined in Equation 1.

$$Cstg = ɛ \frac{A}{d} \qquad \text{<Equation 1>}$$

where, A denotes the area of the first storage electrode STE1, d denotes the distance between the first and second storage electrodes STE1 and STE2, and ∈ denotes the dielectric constant of the dielectric material. For example, d is the thickness of the first gate insulating layer 132, and ∈ is the dielectric constant of the first gate insulating layer 132.

Referring to Equation 1, although the first storage electrode STE1 is formed to have the small area A, a substantially sufficient capacitance Cstg of the storage capacitor CST may be obtained by forming the first and second storage electrodes STE1 and STE2 to have the small distance d.

Therefore, when the first gate insulating layer is formed to have the thickness of about 500 Å to about 1,200 Å with the silicon oxide, the aperture ratio may be enhanced by reducing the area of the first storage electrode STE1.

Table 1 shows a decreasing ratio of the area A according to a thickness d of the storage capacitor.

TABLE 1

| | Example 1 | Example 2 | Example 3 |
|---|---|---|---|
| Both edge | Gate metallic layer | Gate metallic layer | Gate metallic |
| electrodes | Transparent | Source metallic | layer |
| | conductive layer | layer | Source metallic |
| | | | layer |
| Dielectric | Gate insulating layer | Gate insulating | Gate insulating |
| | Passivation layer | layer | layer |
| Thickness | 4,000 Å + 2,000 Å | 4,000 Å | 750 Å |
| Area | 20% | 16% | 4% |
| occupation | | | |
| ratio | | | |
| Decreasing | 0% | 20% | 80% |
| ratio | | | |

Referring to Table 1, in Example 1, both edge electrodes of the storage capacitor are formed from the gate metallic layer and the transparent conductive layer, and the dielectric is formed from the gate insulating layer and a passivation layer to have the thickness of about 6,000 Å. The storage capacitor is formed to occupy about 20% of the total area of each of the pixel portions.

In Example 2, both edge electrodes of the storage capacitor are formed from the gate metallic layer and the source metallic layer, and the dielectric is formed from the gate insulating layer to have the thickness of about 4,000 Å. The thickness of the dielectric in Example 2 is formed to be thinner than that in Example 1 by 2,000 Å. Thus, the storage capacitor is formed to occupy about 16% of the total area of each of the pixel portions. The area of the storage capacitor in Example 2 is reduced by about 20% in comparison to that in Example 1.

In the storage capacitor according to the example embodiment, both edge electrodes of the storage capacitor are formed from the gate metallic layer and the source metallic layer, and the dielectric is formed from the gate insulating layer to have the thickness of about 750 Å. The storage capacitor is formed to occupy about 4% of the total area of each of the pixel portions. Thus, the area of the storage capacitor in the example embodiment, is reduced by about 80% in comparison to that in Example 1, and about 75% in comparison to that in Example 2.

The area A of the storage capacitor CST is reduced, as the thickness d of the dielectric becomes thinner. Therefore, when the first gate insulating layer 132 that is the dielectric of the storage capacitor CST in the example embodiment, is formed to have the thin thickness, the aperture ratio may be enhanced by reducing the area of the storage capacitor CST. For example, the area of the storage capacitor CST may be formed to occupy of about 3% to about 10% of the total area of each of the pixel portions P, as the thickness of the first gate insulating layer 132 becomes thinner.

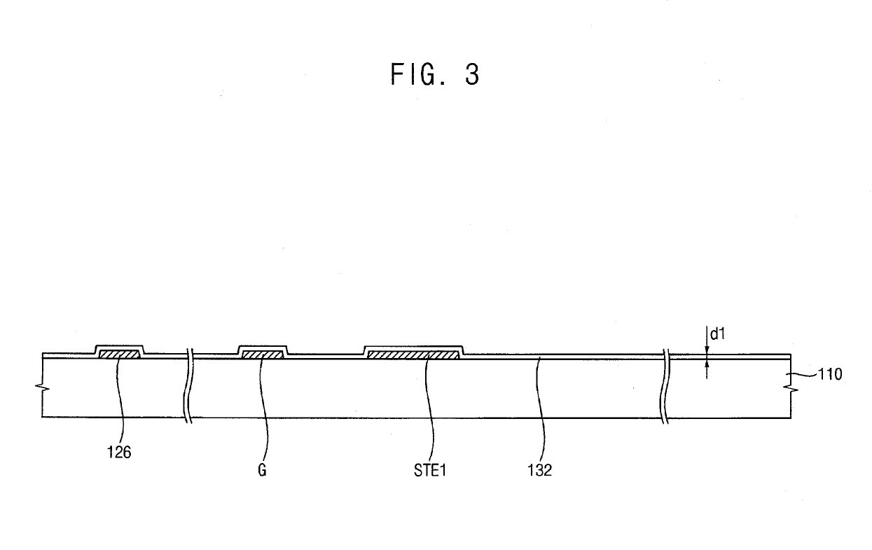

FIGS. 3 to 9 are process views illustrating a method for manufacturing the display substrate in FIG. 2.

Referring to FIGS. 1 and 3, a gate metallic layer is deposited on the first base substrate 110 and is patterned, to form a gate metallic pattern.

The gate metallic pattern includes a gate line GL, a gate electrode G of a switching element TFT, a storage line SCL and a first storage electrode STE1 electrically connected to the storage line SCL. The gate line GL includes an end portion 126, and a gate pad portion GP is formed on the end portion 126 of the gate line GL.

A first gate insulating layer 132 is formed on the first base substrate 110 having the gate metallic pattern, to have a first thickness d. The first gate insulating layer 132 includes a highly insulating material, and has the first thickness d of about 500 Å to about 1,200 Å. Preferably, the first gate insulating layer includes silicon oxide (SiO₂).

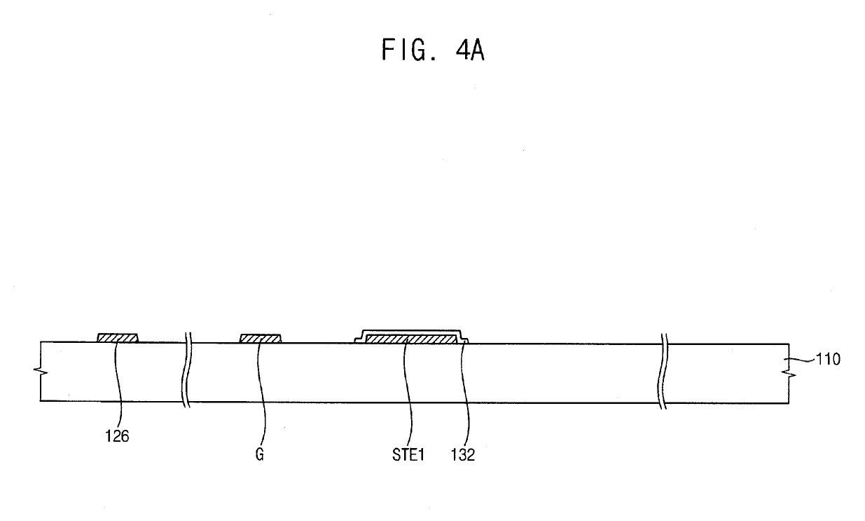

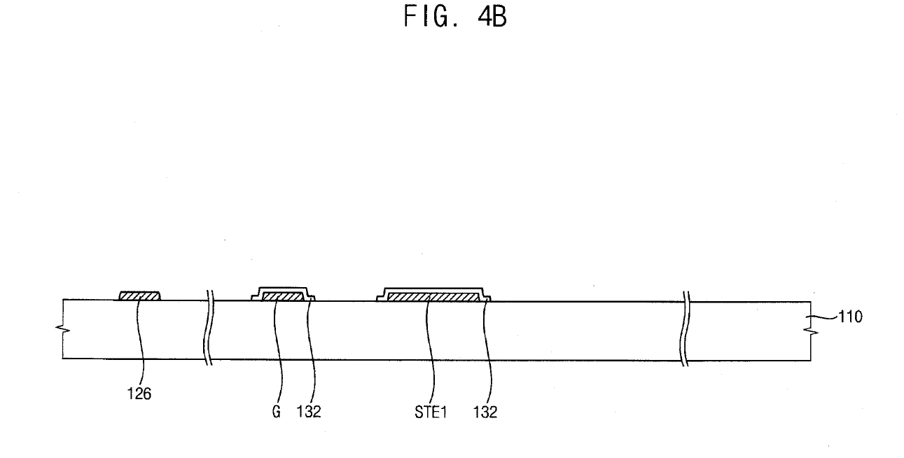

Referring to FIGS. 1, 4A and 4B, the first gate insulating layer 132 is patterned to cover at least one of the gate electrode G and the first storage electrode STE1.

For example, as illustrated in FIG. 4A, the first gate insulating layer 132 may be patterned to cover only the first storage electrode STE1.

When the gate metallic pattern is formed to have the Mo/Al structure having low resistance, the molybdenum, which has good adhesive properties but relatively poor inner resistance, may be damaged in the patterning process. For example, when etching the first gate insulating layer 132 having the thickness of about 500 Å to about 1,200 Å, damage may be done to the gate metallic pattern that has been exposed by the patterning of the first gate insulating layer 132. The damage to the gate metallic pattern may adversely affect the electrical characteristics of the gate pad portion CP. Therefore, to avoid the deterioration of the electrical characteristics, a connecting pattern 162 that contacts the end portion 126 of the gate line GL, is formed in a following process that forms a source metallic pattern.

For example, as illustrated in FIG. 4B, the first gate insulating layer 132 may be patterned to cover not only the gate electrode G but also the first storage electrode STE1. For example, the first gate insulating layer 132 may be formed on the first storage electrode STE1, and the first gate insulating layer 132 may be formed on the gate electrode G.

The example embodiment as illustrated in FIG. 4A will be explained below.

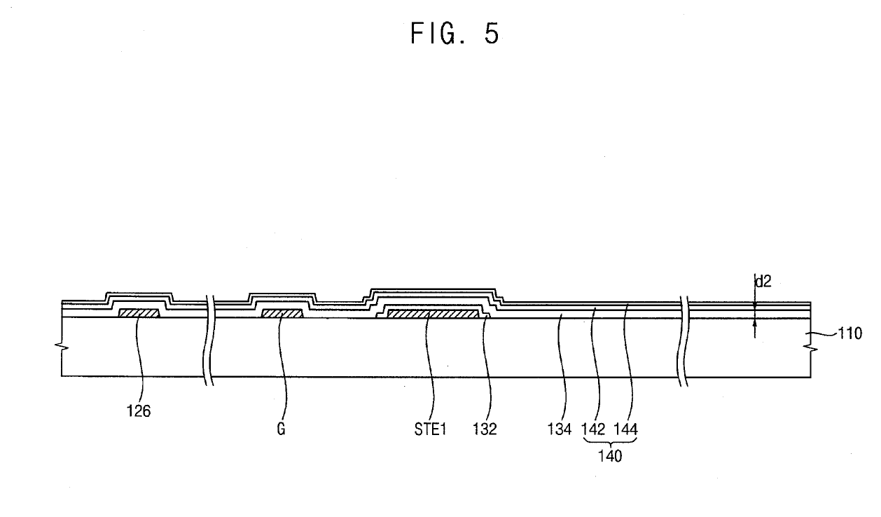

Referring to FIGS. 1 and 5, a second gate insulating layer 134 is formed on the first base substrate 110 having the first gate insulating layer 132 formed on the first storage electrode STE1, to have a second thickness d2. The second gate insulating layer 134 includes the silicon nitride (SiNx), and is formed to have the second thickness d2 of about 3,000 Å to about 4,500 Å.

A channel layer 140 is formed on the first base substrate 110 having the second gate insulating layer 134. The channel layer 140 includes an active layer 142 and a resistant contact layer 144. The active layer 142 is formed by sequentially stacked amorphous silicon (a-Si), and the resistant contact layer 144 is formed by amorphous silicon doped with N+ ion (N+ a-Si) at a high concentration.

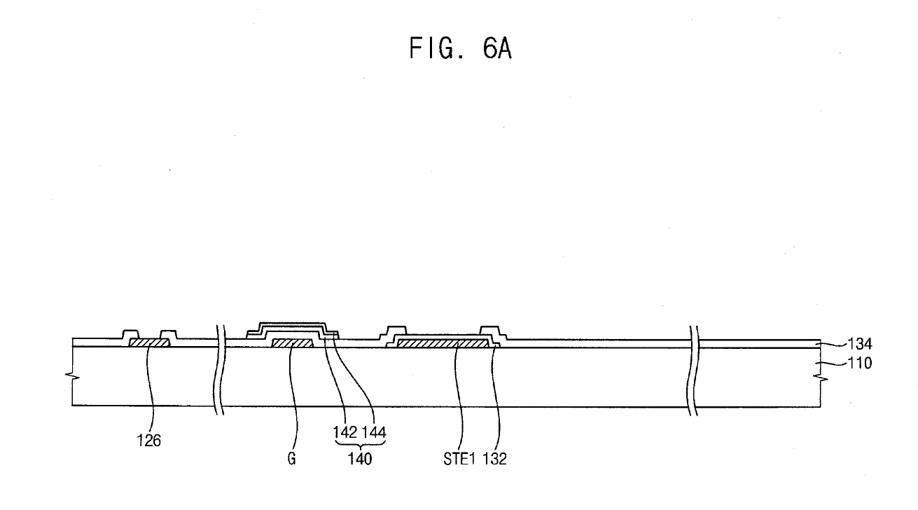

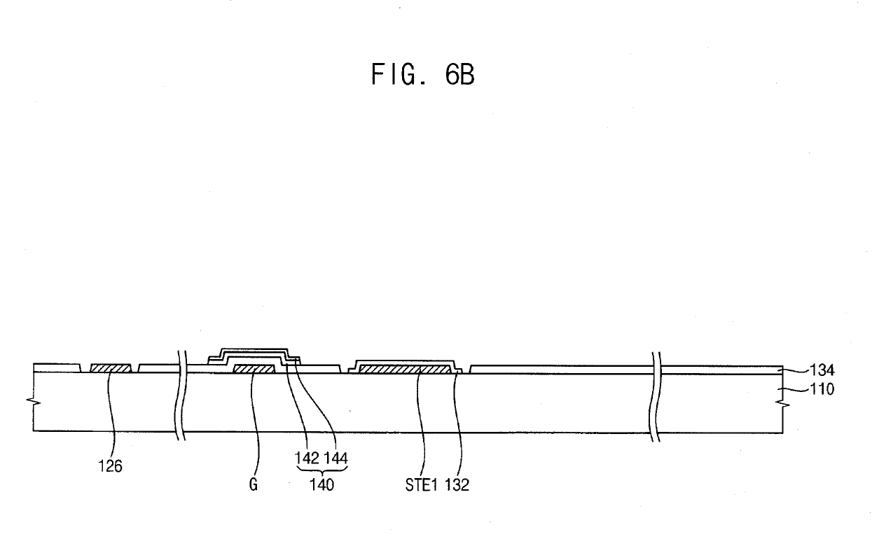

Referring to FIGS. 1, 6A and 6B, the channel layer 140 is patterned, so that the channel layer 140 remains on the second gate insulating layer 134 that is formed on the gate electrode G.

Then, the second gate insulating layer 134 is patterned, to expose the first gate insulating layer 132 on the first storage electrode STE1, and to expose the end portion 126 of the gate line. In this case, the first gate insulating layer 132 and the second gate insulating layer 134 have different etching selection ratios. Thus, the first gate insulating layer 132 is not etched, but the second gate insulating layer 134 is etched.

For example, as illustrated in FIG. 6A, the second gate insulating layer 134 may be patterned to be applied on both edges of the first storage electrode STE1 and the end portion 126 of the gate line. Alternatively, as illustrated in FIG. 6B, the second gate insulating layer 134 may be patterned not to be applied on the first storage electrode STE1 and the end portion 126 of the gate line. The second gate insulating layer 134, which is patterned to be piled on both edges of the first storage electrode STE1 and the end portion 126 of the gate line, will be explained as follows.

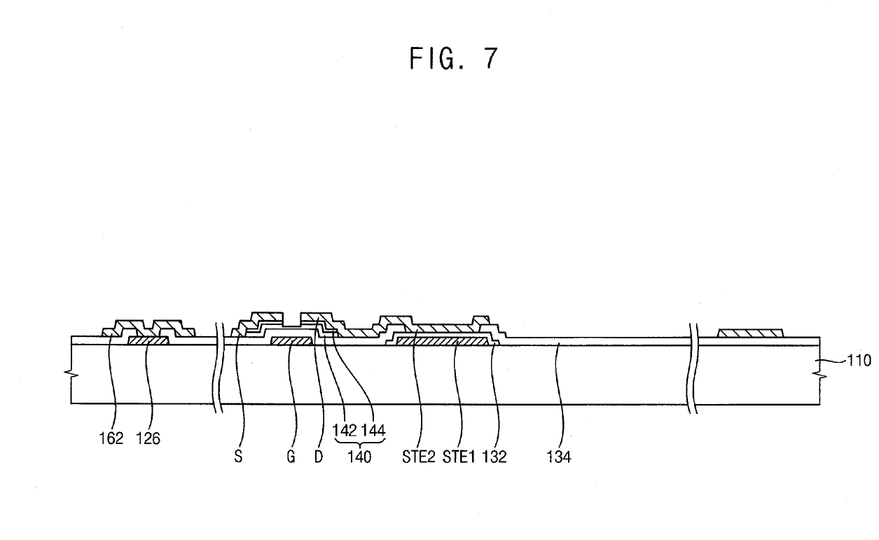

Referring to FIGS. 1 and 7, a source metallic layer is deposited on the first base substrate 110 having the second gate insulating layer 134, and the source metallic layer is patterned to form a source metallic pattern.

The source metallic pattern includes the source line DL, a source electrode S and a drain electrode D of the switching element TFT, a second storage electrode STE2 of the storage capacitor CST, and a connecting pattern 162 of the gate pad portion GP. The second storage electrode STE2 contacts the first gate insulating layer 132 on the first storage electrode STE1. The connecting pattern 162 contacts the end portion 126 of the gate line, to enhance electrical characteristics of the gate pad portion GP. The source line DL includes an end portion 164 of the source line, and the source pad portion DP is formed on the end portion 164 of the source line.

Then, the resistant contact layer 144 that is exposed between the source electrode S and the drain electrode D, is etched using the source metallic pattern as a mask, so that a channel of the switching element TFT is formed.

Therefore, the storage capacitor CST includes the first storage electrode STE1, the second storage electrode STE2, and the first gate insulating layer 132 disposed between the first and second storage electrodes STE1 and STE2.

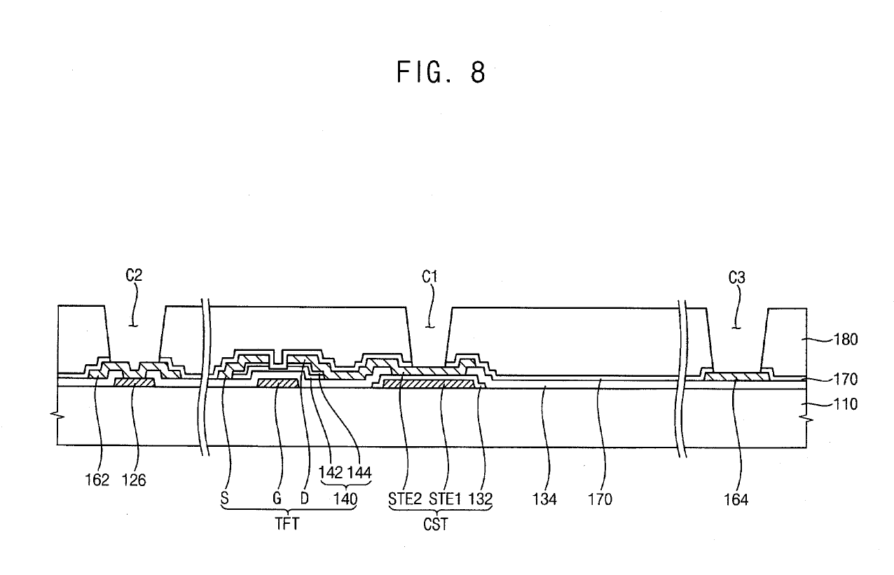

Referring to FIGS. 1 and 8, a passivation layer 170 and an organic layer 180 are sequentially formed on the first base substrate 110 having the source metallic pattern. The thickness of the passivation layer 170 is about 2,000 Å. Example materials that may be used for the passivation layer 170 include silicon nitride or silicon oxide.

Then, the passivation layer 170 and the organic layer 180 are patterned to form a first contact hole C1 exposing the second storage electrode STE2, a second contact hole C2 exposing the connecting pattern 162 of the gate pad portion GP, and a third contact hole C3 exposing the end portion 164 of the source line of the source pad portion DP.

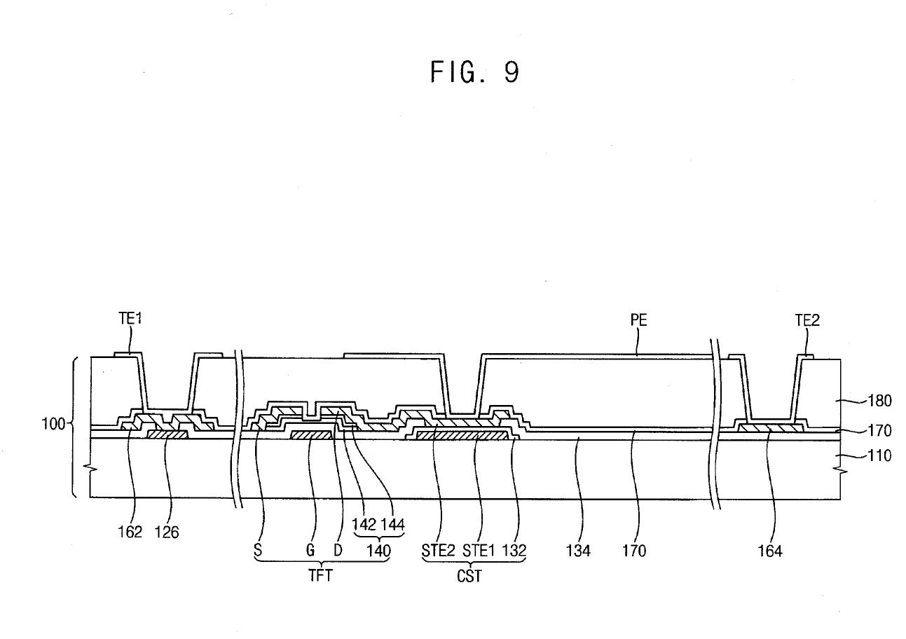

Referring to FIGS. 1 and 9, a transparent conductive layer is deposited on the first base substrate 110 having the first, second and third contact holes C1, C2 and C3, and is patterned to form a transparent electrode pattern. The transparent electrode pattern includes a pixel electrode PE contacting the second storage electrode STE2 through the first contact hole C1, a first pad pattern TE1 contacting the connecting pattern 162 through the second contact hole C2, and a second pad pattern TE2 contacting the end portion 164 of the source line through the third contact hole C3.

According to the present invention, a gate insulating layer is formed with a multi-layer structure including first and second gate insulating layers having different etching selection ratios, the first gate insulating layer being applied as a thin dielectric layer of the storage capacitor and the second gate insulating layer being applied to the insulating layer to electrically insulating the gate electrode. In this case, the first gate insulating layer is formed as a thin layer, and the second gate insulating layer is formed with substantially the same thickness as that of a conventional gate insulating layer.

Particularly, the first electrode of the storage capacitor is formed from the gate metallic layer, the second electrode is formed from the source metallic layer, and the thin first gate insulating layer is formed between the first and second electrodes so that the occupying area of the storage capacitor in the pixel portion is reduced and a display substrate having a high aperture ratio is achieved.

Alternatively, the second gate insulating layer is used for the insulating layer that electrically insulates the gate electrode, so that the electrical characteristics of the switching element may be maintained and the aperture ratio may be enhanced.

Having described the example embodiments of the present invention and its advantages, it is noted that various changes, substitutions and alterations can be made herein without departing from the spirit and scope of the invention as defined by the appended claims.

What is claimed is:

1. A display substrate comprising:
a gate metallic pattern including a gate line, a gate electrode of a switching element and a first storage electrode;
a first gate insulating layer covering at least one of the gate electrode and the first storage electrode;
a second gate insulating layer patterned to expose the first gate insulating layer on the first storage electrode;
a source metallic pattern including a second storage electrode, the second storage electrode contacting a source line and the first gate insulating layer on the first storage electrode; and
a pixel electrode electrically connected to the switching element.

2. The display substrate of claim 1, wherein the first gate insulating layer has a thickness of about 500 Å to about 1,200 Å.

3. The display substrate of claim 2, wherein the first gate insulating layer comprises silicon oxide.

4. The display substrate of claim 2, wherein the second gate insulating layer comprises silicon nitride.

5. The display substrate of claim 2, wherein a pixel portion is defined by the adjacent gate lines and the adjacent source lines, and an area of the first storage electrode is about 3% to about 10% of that of the pixel portion.

6. The display substrate of claim 1, further comprising a gate pad portion that applies a gate signal to the gate line.

7. The display substrate of claim 6, wherein the gate pad portion comprises a connecting pattern being formed from the same layer as the source line to contact an end portion of the gate line, and a pad pattern being formed from the same layer as the pixel electrode to contact the connecting pattern.

8. A method for manufacturing a display substrate, comprising:
forming a gate metallic pattern on a base substrate from a gate metallic layer, the gate metallic pattern including a gate line, a gate electrode of a switching element and a first storage electrode;
forming a first gate insulating layer on the base substrate having the gate metallic pattern;
patterning the first gate insulating layer, to cover at least one of the gate electrode and the first storage electrode;
forming a second gate insulating layer, the second gate insulating layer being formed on the base substrate having the patterned first gate insulating layer and being patterned to expose the first gate insulating layer on the first storage electrode;
forming a second storage electrode, the second storage electrode being formed from a source metallic layer to contact a source line and the first gate insulating layer on the first storage electrode, the first gate insulating layer being exposed through the second gate insulating layer; and
forming a pixel electrode, the pixel electrode being formed from a transparent conductive layer to be electrically connected to the switching element.

9. The method of claim 8, further comprising forming a gate pad portion applying a gate signal to the gate line.

10. The method of claim 9, wherein forming the gate pad portion comprises:
patterning the second gate insulating layer, to expose an end portion of the gate line;
forming a connecting pattern from the source metallic layer, to contact the end portion; and
forming a pad pattern from the transparent conductive layer, to contact the connecting pattern.

11. The method of claim 8, wherein the first gate insulating layer and the second gate insulating layer have different etching selection ratios.

12. The method of claim 8, wherein the first gate insulating layer has a thickness of about 500 Å to about 1,200 Å.

13. The method of claim 12, wherein the first gate insulating layer comprises silicon oxide.

14. The method of claim 13, wherein the second gate insulating layer comprises silicon nitride.

15. A display apparatus comprising:
a display substrate including a first gate insulating layer patterned to cover at least one of a gate electrode of a switching electrode and a first storage electrode,
a second gate insulating layer patterned to expose the first gate insulating layer on the first storage electrode,
a second storage electrode contacting the first gate insulating layer on the first storage electrode,
a pixel electrode electrically connected to the switching element;
a counter substrate combined with the display substrate to receive a liquid crystal layer, and
a common electrode facing the pixel electrode formed on the counter substrate.

16. The display apparatus of claim 15, wherein the first gate insulating layer has a thickness of about 500 Å to about 1,200 Å.

17. The display apparatus of claim 15, wherein the display substrate further comprises a gate line being electrically connected to the gate electrode and a gate pad portion applying a gate signal to the gate line, and
wherein the gate pad portion comprises a connecting pattern contacting an end portion of the gate line and a pad pattern contacting the connecting pattern.
